(19) United States
(12) Patent Application Publication
(10) Pub. No.: US 2021/0341847 A1
(43) Pub. Date: Nov. 4, 2021

(54) METHOD AND APPARATUS FOR ANALYZING PARAMETER OF MASK PLATE

(71) Applicant: CHANGXIN MEMORY TECHNOLOGIES, INC., Hefei City (CN)

(72) Inventor: Jiangjiao ZU, Hefei (CN)

(21) Appl. No.: 17/373,899

(22) Filed: Jul. 13, 2021

Related U.S. Application Data
(63) Continuation of application No. PCT/CN2021/078850, filed on Mar. 3, 2021.

(30) Foreign Application Priority Data
Mar. 3, 2020 (CN) 202010141623.6

(51) Int. Cl. G03F 7/20

(52) U.S. Cl. CPC G03F 7/70683; G03F 7/70633; G03F 7/70508

(57) ABSTRACT

A method and apparatus for analyzing a parameter of a mask plate is provided. A detection parameter of at least one mask pattern is acquired, and the detection parameter includes a deviation coordinate between a measurement coordinate of each alignment mark in a mask pattern manufactured with a mask plate and a preset coordinate of each alignment mark in a layout of the mask pattern. A direction and a vector length of a deviation vector of the deviation coordinate of each alignment mark in the mask pattern are acquired according to the detection parameter. Quality analysis data of the mask plate is generated according to the direction and the vector length of the deviation vector of each alignment mark in the mask pattern.

### CROSS-REFERENCE TO RELATED APPLICATIONS

The present application is a U.S. continuation application of International Application No. PCT/CN2021/078850, filed on Mar. 3, 2021, which claims priority to Chinese patent application No. 202010141623.6, filed on Mar. 3, 2020. International Application No. PCT/CN2021/078850 and Chinese patent application No. 202010141623.6 are incorporated herein by reference in their entireties.

### TECHNICAL FIELD

The embodiments of the disclosure relate to the technical field of semiconductor manufacture procedures, and more particularly, to a method and apparatus for analyzing a parameter of a mask plate.

### BACKGROUND

As a carrier of graphical information, the mask plate transfers a pattern to an exposed product by means of an exposure process, thereby implementing the transfer of the pattern. For example, during manufacture procedures of chips, the pattern on the mask plate is coped to a silicon wafer through a photolithography technology to form a corresponding device.

Typically, an alignment mark is respectively provided on the silicon wafer and the mask plate. During exposure, the pattern on the mask plate cannot be accurately coped to a corresponding position on the silicon wafer, until the alignment mark of the mask plate is aligned to that of the silicon wafer, i.e., the alignment mark plays an alignment role in manufacture of optical masks, and is a key element to evaluate the optical masks. In the conventional art, upon the complete manufacture of the mask plate, coordinate information of the alignment mark of the mask plate is detected, to acquire a deviation between the actual alignment mark of the mask plate and the alignment mark of the design layout; and a detection report is generated for detection data of alignment marks of mask plates in mass production, to view and screen qualified or unqualified mask plates.

However, in the conventional art, the detection report for the alignment data of the mask plates is analyzed artificially and whether the mask plate is qualified is determined artificially. Hence, the strong subjectivity on artificial determination in the conventional art will cause a determination error to the quality of the mask plates, and the determination efficiency is low.

### SUMMARY

For the above problem, the embodiments of the disclosure provide a method and apparatus for analyzing a parameter of a mask plate, to improve the analysis efficiency on alignment data of the mask plate, and improve the accuracy of the analysis result.

According to a first aspect, the embodiments of the disclosure provide a method for analyzing a parameter of a mask plate, which includes the following steps.

Acquiring a detection parameter of at least one mask pattern, wherein the detection parameter includes a deviation coordinate between a measurement coordinate of each alignment mark in a mask pattern manufactured with the mask plate and a preset coordinate of each alignment mark in a layout of the mask pattern;

acquiring a direction and a vector length of a deviation vector of the deviation coordinate of each alignment mark in the mask pattern according to the detection parameter;

generating quality analysis data of the mask plate according to the direction and the vector length of the deviation vector of each alignment mark in the mask pattern.

According to a second aspect, the embodiments of the disclosure provide an apparatus for analyzing a parameter of a mask plate, which includes:

a detection parameter acquisition module, configured to acquire a detection parameter of at least one mask pattern, wherein the detection parameter includes a deviation coordinate between a measurement coordinate of each alignment mark in a mask pattern manufactured with a mask plate and a preset coordinate of each alignment mark in a layout of the mask pattern;

a deviation vector acquisition module, configured to acquire, according to the detection parameter, a direction and a vector length of a deviation vector of the deviation coordinate of each alignment mark in the mask pattern.

an analysis data generation module, configured to generate quality analysis data of the mask plate according to the direction and the vector length of the deviation vector of each alignment mark in the mask pattern.

The method and apparatus for analyzing the parameter of the mask plate provided by the embodiments of the disclosure acquire, through the detection parameter of the mask pattern, the deviation coordinate between each alignment mark in the mark pattern manufactured with the mask plate and each alignment mark in the layout of the mask pattern, obtain the direction and the vector length of the deviation vector of each alignment mark in the mask pattern according to the deviation coordinate, and generate the quality analysis data of the mask plate for manufacturing the mask pattern, such that the quality of the mask plate can be analyzed. Therefore, through the detection parameter of the mask pattern, the quality analysis data of the mask plate are acquired automatically. The disclosure can improve the analysis efficiency of the mask plate, can eliminate a quality analysis error arising from subjective factors, can save the labor cost of quality analysis, reducing the cost for the quality analysis of the mask plate.

### BRIEF DESCRIPTION OF THE DRAWINGS

FIG. 1 illustrates a flowchart of a method for analyzing a parameter of a mask plate provided by an embodiment of the disclosure.

FIG. 2A-FIG. 2D illustrate schematic diagrams of deviation vector provided by an embodiment of the disclosure.

FIG. 3 illustrates a structural schematic diagram of a contrast statistics for different mask patterns provided by an embodiment of the disclosure.

FIG. 4 illustrates a structural schematic diagram of another contrast statistics for different mask patterns provided by an embodiment of the disclosure.

FIG. 5 illustrates a flowchart of a specific method for acquiring a deviation vector provided by an embodiment of the disclosure.

FIG. 6 illustrates a top view of structural schematic diagram of a mask pattern for plotting a deviation vector provided by an embodiment of the disclosure.

FIG. 7 illustrates a top view of structural schematic diagram of a mask pattern for plotting a vector matrix provided by an embodiment of the disclosure.

FIG. 8 illustrates a flowchart of another method for analyzing a mask plate provided by an embodiment of the disclosure.

FIG. 9 illustrates a flowchart of another method for analyzing a mask plate provided by an embodiment of the disclosure.

FIG. 10 illustrates a flowchart of another method for analyzing a parameter of a mask plate provided by an embodiment of the disclosure.

FIG. 11 illustrates a structural schematic diagram of an apparatus for analyzing a mask plate provided by an embodiment of the disclosure.

FIG. 12 illustrates a structural schematic diagram of another apparatus for analyzing a mask plate provided by an embodiment of the disclosure.

### DETAILED DESCRIPTION

The disclosure will be further described below in detail in combination with the accompanying drawings and the embodiments. It is to be understood that the specific embodiments described herein are merely used for explaining the disclosure, rather than limiting the disclosure. In addition, it is further to be noted that, for the ease of description, only the parts related to the disclosure, rather than all structures, are shown in the accompanying drawings.

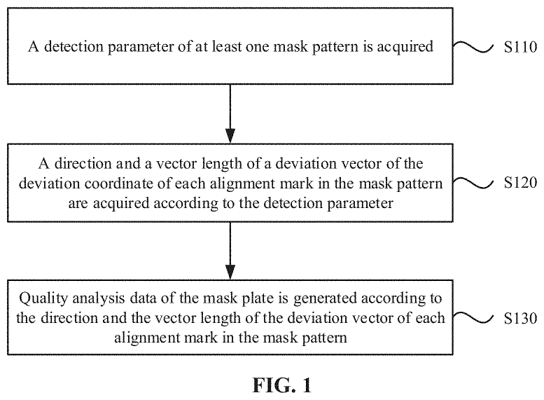

The embodiments of the disclosure provide a method for analyzing a parameter of a mask plate. The method may be applied to a situation for analyzing performance and quality of the mask plate. The method for analyzing the parameter of the mask plate provided by the embodiments of the disclosure may be executed by an apparatus for analyzing the parameter of the mask plate provided by the embodiments of the disclosure. The apparatus may be implemented by software and/or hardware. FIG. 1 illustrates a flowchart of a method for analyzing a parameter of a mask plate provided by an embodiment of the disclosure. As shown in FIG. 1, the method includes the following steps.

At S110, a detection parameter of at least one mask pattern is acquired, wherein the detection parameter includes a deviation coordinate between a measurement coordinate of each alignment mark in a mask pattern manufactured with a mask plate and a preset coordinate of each alignment mark in a layout of the mask pattern.

In some embodiments, during manufacture procedures of semiconductor devices, mask plates may be exposed and developed to form corresponding mask patterns, such that structures of the devices are formed at corresponding positions of integrated chips. The mask plates may typically be manufactured with a layout of the mask patterns. In order that each device is accurately formed at the corresponding position, when the layout of the mask pattern is designed, there is a corresponding alignment mark designed on the mask pattern, and an alignment mark provided on the mask plate, so as to align the position of the mask plate with the alignment mark during exposure and development. Correspondingly, the mask pattern formed with the mask plate not only includes the structure of the device, and but also includes the corresponding alignment mark. The alignment mark is typically provided in a cutting channel region among multiple integrated chips manufactured with a same wafer, so as to prevent the alignment mark from affecting the structure of the device in the integrated chip. In this way, by measuring a position coordinate of the alignment mark on the mask pattern manufactured with the mask plate, a measurement coordinate of each alignment mark in the mask pattern manufactured with the mask plate may be known; and by comparing the measurement coordinate with a preset coordinate of the alignment mark on the layout of the mask pattern one by one, a deviation coordinate between each alignment mark in the mask pattern actually manufactured with the mask plate and each alignment mark in the layout of the mask pattern may be obtained. For each mask pattern, a detection report for the deviation coordinate of the alignment mark may be formed to serve as the detection parameter of the mask pattern. The performance and quality of the mask plate may be detected by acquiring detection data of the mask pattern.

Acquiring detection data of at least one mask pattern may be to acquire detection data of one mask pattern, or acquire detection data of multiple mask pattern. The multiple mask patterns may be multiple mask patterns formed with the same mask plate by multiple times of exposure and development, and may also be multiple mask patterns formed with different mask plates by exposure and development, which is not specifically limited thereto in the embodiment of the disclosure.

At S120, a direction and a vector length of a deviation vector of the deviation coordinate of each alignment mark in the mask pattern are acquired according to the detection parameter.

In some embodiments, the vector has a direction and a magnitude. A positive or negative value of the vector coordinate can be determined through the direction of the vector, and a deviation between the vector coordinate and an origin can be determined through the magnitude of the vector length. As the detection parameter of the mask pattern is the deviation coordinate between the measurement coordinate of each alignment mark in the mask pattern manufactured with the mask plate and the preset coordinate of each alignment mark in the layout of the mask pattern, the coordinate value of the deviation coordinate may include a positive coordinate value and/or a negative coordinate value, i.e., being in an X direction or a Y direction of a plane. When the coordinate value of the alignment mark in the mask pattern manufactured with the mask plate is greater than the coordinate value of the alignment mark in the layout of the mask pattern, the deviation coordinate has a positive coordinate value; and when the coordinate value of the alignment mark in the mask pattern manufactured with the mask plate is less than the coordinate value of the alignment mark in the layout of the mask pattern, the deviation coordinate has a negative coordinate value Therefore, according to the positive or negative coordinate value in the deviation coordinate of each alignment mark in the mask pattern, a deviation direction of the deviation vector of each alignment mark in the mask pattern may be obtained; and meanwhile, the vector length of the deviation vector may be obtained from the deviation coordinate. The mode for acquiring the direction and vector length of the deviation vector may be that they are obtained through a corresponding algorithm according to the detection parameter, or that a corresponding coordinate system is established and the deviation vector is labeled in the layout of the mask pattern.

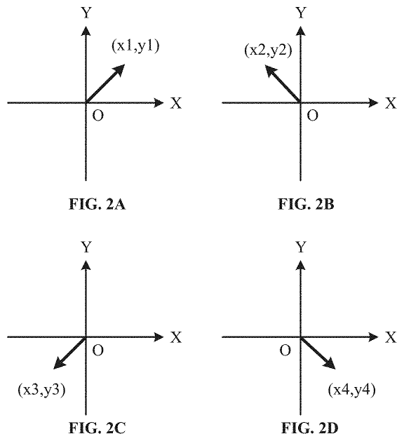

Exemplarily, FIG. 2 illustrates a structural schematic diagram of a deviation vector provided by an embodiment of the disclosure. As shown in FIG. 2, after the deviation coordinate of the alignment mark in the mask pattern manufactured with the mask plate is acquired, the deviation vector corresponding to each deviation coordinate may be labeled in the layout of the mask pattern. By this time, a coordinate system is established with the preset coordinate of the alignment mark in the layout of the mask pattern as an origin of coordinates O; and with the origin of coordinates O as a start point O of the deviation vector, and the deviation coordinate as an end point of the deviation vector, the deviation vector corresponding to the deviation coordinate as well as a quadrant where the deviation vector is located, and a direction of the deviation vector may be obtained; and the vector length of the deviation vector is obtained from a coordinate of the deviation vector. As shown in FIG. 2A, when the measurement coordinate of the alignment mark in the mask pattern manufactured with the mask plate is (x11, y11), and the preset coordinate of the alignment mark in the layout of the mask pattern is (x12, y12), the deviation coordinate (x1, y1) is (x11-x12, y11-y12); if both x11-x12 and y11-y12 are greater than 0, then the deviation vector is located in a first quadrant of the coordinate system, and accordingly, the direction of the deviation vector may be obtained and the length of the deviation vector may be calculated through the deviation coordinate (x1, y1). As shown in FIG. 2B, when the measurement coordinate of the alignment mark in the mask pattern manufactured with the mask plate is (x21, y21), and the preset coordinate of the alignment mark in the layout of the mask pattern is (x22, y22), the deviation coordinate (x2, y2) is (x21-x22, y21-y22); if x21-x22 is less than 0 and y21-y22 is more than 0, then the deviation vector is located in a second quadrant of the coordinate system, and accordingly, the direction of the deviation vector may be obtained and the length of the deviation vector may be calculated through the deviation coordinate (x2, y2). As shown in FIG. 2C, when the measurement coordinate of the alignment mark in the mask pattern manufactured with the mask plate is (x31, y31), and the preset coordinate of the alignment mark in the layout of the mask pattern is (x32, y32), the deviation coordinate (x3, y3) is (x31-x32, y31-y32); if both x31-x32 and y31-y32 are less than 0, then the deviation vector is located in a third quadrant of the coordinate system, and accordingly, the direction of the deviation vector may be obtained and the length of the deviation vector may be calculated through the deviation coordinate (x3, y3). As shown in FIG. 2D, when the measurement coordinate of the alignment mark in the mask pattern manufactured with the mask plate is (x41, y41), and the preset coordinate of the alignment mark in the layout of the mask pattern is (x42, y42), the deviation coordinate (x4, y4) is (x41-x42, y41-y42); if x41-x42 is greater than 0 and y41-y42 is less than 0, then the deviation vector is located in a fourth quadrant of the coordinate system, and accordingly, the direction of the deviation vector may be obtained and the length of the deviation vector may be calculated through the deviation coordinate (x4, y4).

At S130, quality analysis data of the mask plate is generated according to the direction and the vector length of the deviation vector of each alignment mark in the mask pattern.

In some embodiments, according to the deviation vector of each alignment mark in the mask pattern manufactured with the mask plate, a deviation and a deviation direction of each alignment mark in the mask pattern manufactured with the mask plate relative to the alignment mark in the layout of the mask pattern may be acquired. As the alignment mark of the mask pattern manufactured with the mask plate and the alignment mark on the mask plate are in a one-to-one corresponding relation, a deviation and a deviation direction of the alignment mark in the mask plate for manufacturing the mask pattern can be determined through the deviation and the deviation direction of the alignment mark in the mask pattern, to generate the quality analysis data of the mask plate according to the deviation and the deviation direction.

The quality analysis data may include one or more of relation data between an average value for the vector length of the deviation vector and a reference value, relation data between a vector length of a deviation vector having a maximum vector length in the deviation vector and a reference value, and relation data between a vector length of a deviation vector having a minimum vector length in the deviation vector and a reference value. Therefore, the quality of the corresponding mask plate may be analyzed and evaluated according to an extreme value and/or an average of the deviation vector. Exemplarily, when the vector length of the deviation vector having the maximum vector length in the deviation vector of the mask pattern is less than the reference value, the larger the difference value between the reference value and the vector length of the deviation vector having the maximum vector length, the more excellent the performance of the mask plate for manufacturing the mask pattern; or, the performance of the mask plate for manufacturing the mask pattern may be determined in combination with the average value of the vector length of the deviation vector in the mask pattern and the vector length of the deviation vector having the maximum vector length. When detection parameters of multiple mask patterns are acquired, the multiple mask patterns may be mask patterns of different devices manufactured with a same mask plate, or mask patterns of different film layers of a same device that are manufactured with different mask plates. By this time, the quality analysis data of the mask plate may be contrast statistical data among different mask patterns. The contrast statistical data may be presented in the form of a table, a histogram or a percentage or the like.

The embodiment acquires, through the detection parameter of the mask pattern, the deviation coordinate between each alignment mark in the mark pattern manufactured with the mask plate and each alignment mark in the layout of the mask pattern, obtain the direction and the vector length of the deviation vector of each alignment mark in the mask pattern according to the deviation coordinate, and generate the quality analysis data of the mask plate for manufacturing the mask pattern, such that the quality of the mask plate can be analyzed. Therefore, through the detection parameter of the mask pattern, the quality analysis data of the mask plate is acquired automatically. The disclosure can improve the analysis efficiency of the mask plate, can eliminate a quality analysis error arising from subjective factors, can save the labor cost of quality analysis, and reduces the cost for the quality analysis of the mask plate.

In some embodiments, when the acquired detection parameter of the at least one mask pattern is detection parameters of multiple mask patterns, a direction and a vector length of a deviation vector of a deviation coordinate of each alignment mark in each mask pattern may be respectively obtained according to a detection parameter of each mask pattern. The step that the quality analysis data of the mask plate is generated according to the direction and the vector length of the deviation vector of each alignment mark in each mask pattern is specifically as follows: according to a vector length average value of the deviation vector of each alignment mark in each mask pattern, a relation diagram between the vector length average value of each mask pattern and a reference value is generated; or, according to a maximum vector length of the deviation vector of each alignment mark in each mask pattern, a relation diagram between the maximum vector length of each mask pattern and a reference value is generated; or, according to a minimum vector length of the deviation vector of each alignment mark in each mask pattern, a relation diagram between the minimum vector length of each mask pattern and a reference value is generated; or, according to a deviation coordinate of the deviation vector having the maximum vector length from the deviation vector of each alignment mark in each mask pattern, a relation diagram between the deviation coordinate of the deviation vector having the maximum vector length in each mask pattern and a reference coordinate is generated; or, according to a deviation coordinate of the deviation vector having the minimum vector length from the deviation vector of each alignment mark in each mask pattern, a relation diagram between the deviation coordinate of the deviation vector having the minimum vector length in each mask pattern and a reference coordinate is generated.

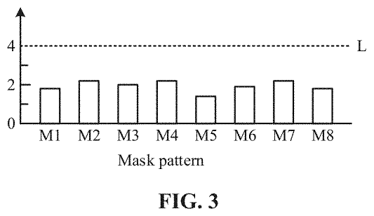

Exemplarily, FIG. 3 illustrates a structural schematic diagram of a contrast statistics for different mask patterns provided by an embodiment of the disclosure. As shown in FIG. 3, a corresponding histogram may be generated by making a statistics of deviation vectors of mask patterns M1-M8. In the histogram, the height may represent a maximum vector length, a minimum vector length, an average value of each vector length, and a coordinate value of a corresponding deviation vector in an X direction or a Y direction in different mask patterns, and the dotted line L may represent an X-coordinate absolute value or a Y-coordinate absolute value in the reference coordinate. Therefore, detection parameter information of each mask pattern can be acquired intuitively through the histogram, and the quality of the mask plate for manufacturing each mask pattern can be analyzed. The reference value may be 4, the reference coordinate may be (4, 4), and the reference value or the reference coordinate is a numerical value meeting the position deviation of each device in the integrated chip. In the histogram of FIG. 3, the heights of columns of the mask patterns M1-M8 are all less than the reference value, such that it may be known that mask plates for manufacturing the mask patterns M1-M8 are qualified mask plates.

It is to be noted that the mask patterns M1-M8 may be represented as the mask pattern M1, the mask pattern M2, the mask pattern M3, the mask pattern M4, the mask pattern M5, the mask pattern M6, the mask pattern M7 and the mask pattern M8. FIG. 3 is merely the exemplary drawing of the embodiment of the disclosure. FIG. 3 exemplarily shows 8 mask patterns. However, the number of mask patterns subjected to contrast statistics in the embodiment of the disclosure may be more than or less than 8. The number of statistical mask patterns and corresponding mask plates are not limited in the embodiment of the disclosure.

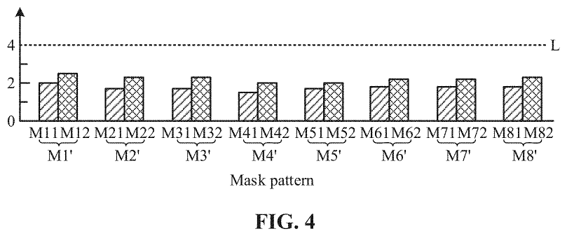

Exemplarily, FIG. 4 illustrates a structural schematic diagram of another contrast statistics for different mask patterns provided by an embodiment of the disclosure. As shown in FIG. 4, M1′-M8′ represent different integrated chips, M11-M81 respectively represent a mask pattern on a first film layer of each integrated chip M1′-M8′, and M12-M82 respectively represent a mask pattern on a second film layer of each integrated chip M1′-M8′. The mask pattern on the first film layer and the mask pattern on the second film layer are respectively formed with different mask plates. Therefore, the quality of the mask plate for manufacturing the first film layer may be analyzed through the height of the histogram corresponding to each M11-M81, and the quality of the mask plate for manufacturing the second film layer may be analyzed through each mask pattern M12-M82.

It is to be noted that both FIG. 3 and FIG. 4 use the histogram to represent a relation between a length of a deviation vector of different mask patterns, a coordinate value in the X direction or a coordinate value in the Y direction and the reference value. In the embodiment of the disclosure, the relation diagram between the length of the deviation vector of each mask pattern, the coordinate value in the X direction or the coordinate value in the Y direction and the reference value may further be formed in the form of the percentage, histogram or broken line graph or the like, which is not specifically limited thereto in the embodiment of the disclosure.

In the embodiment of the disclosure, when detection data of multiple mask patterns are acquired, detection data of the multiple mask patterns may be mask patterns of different film layers in same integrated chip that are manufactured with different mask plates, or mask patterns of different integrated chips that are manufactured with the same mask plate.

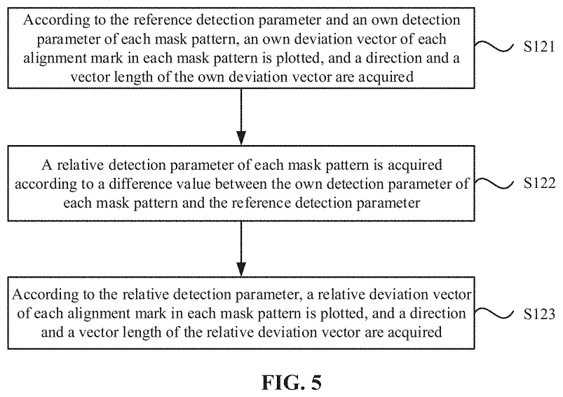

In some embodiments, when the multiple mask patterns are respectively mask patterns of different film layers in a same integrated chip and are manufactured with different mask plates, a detection parameter of one mask pattern among the detection parameters of the multiple mask patterns may be used as a reference detection parameter, and a detection parameter of each of other mask patterns is used as an own detection parameter. Correspondingly, FIG. 5 illustrates a flowchart of a specific method for acquiring a deviation vector provided by an embodiment of the disclosure. As shown in FIG. 5, the method for acquiring the deviation vector of the deviation coordinate of each alignment mark in the mask pattern according to the detection parameter includes the following steps.

At S121, according to the reference detection parameter and an own detection parameter of each mask pattern, an own deviation vector of each alignment mark in each mask pattern is plotted, and a direction and a vector length of the own deviation vector are acquired.

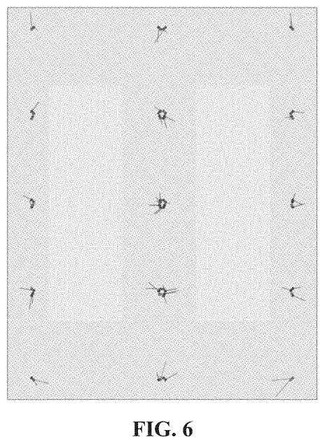

In some embodiments, as the same integrated chip includes multiple film layers, and the mask pattern of each film layer is different, it is necessary that multiple mask plates be used to mask each film layer of the integrated chip to form corresponding mask patterns. A detection parameter of a mask pattern of a reference layer may be used as the reference detection parameter, and a detection parameter of a mask pattern of each of other film layers may be used as an own detection parameter. Exemplarily, FIG. 6 illustrates a top view of structural schematic diagram of a mask pattern for plotting a deviation vector provided by an embodiment of the disclosure. As shown in FIG. 6, an end point of a deviation vector of each alignment mark of the reference layer is determined according to a deviation coordinate of an alignment mark in the reference detection parameter, and a preset coordinate of each alignment mark in a layout of a mask pattern of the reference layer is used as a start point of the deviation vector, such that the deviation vector of the deviation coordinate of each alignment mark in the reference layer can be plotting to the layout of the mask pattern of the reference layer. Meanwhile, lines of different colors may be used to label deviation vectors of different magnitudes. For example, the longer the vector length of the deviation vector, the deeper the color of the line for plotting the deviation vector. Therefore, the direction and the vector length of each deviation vector can be determined intuitively.

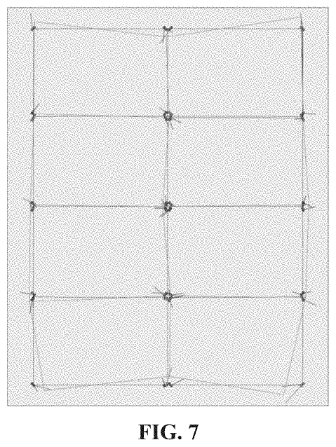

Exemplarily, FIG. 7 illustrates a top view of structural schematic diagram of a mask pattern for plotting a vector matrix provided by an embodiment of the disclosure. As shown in FIG. 7, upon the completion of the plotting of the deviation vector, a vector matrix diagram may further be plotted in the diagram in which the deviation vector is plotted, such that the influence of the deviation coordinate of each alignment mark on the device structure in the integrated chip can be determined more intuitively to facilitate subsequent analysis and adjustment.

At S122, a relative detection parameter of each mask pattern is acquired according to a difference value between the own detection parameter of each mask pattern and the reference detection parameter.

At S123, according to the relative detection parameter, a relative deviation vector of each alignment mark in each mask pattern is plotted, and a direction and a vector length of the relative deviation vector are acquired.

In some embodiments, with reference detection data of the mask pattern of the reference layer as a reference, a relative detection parameter of each mask pattern may be acquired through a difference value between own detection data of a mask pattern of other film layers and reference detection data. The relative detection parameter is a relative coordinate (x-x′, y-y′) between the deviation coordinate (x, y) of the alignment mark in other mask patterns and the deviation coordinate (x′, y′) of the alignment mark in the mask pattern of the reference layer, i.e., a relative coordinate (Δx, Δy).

Exemplarily, Table 1 shows an own detection parameter and a relative detection parameter of a mask pattern of a non-reference layer in an integrated chip. The serial number in Table 1 represents a serial number of each alignment mark in the mask pattern. The above only exemplarily shows own deviation coordinates and relative deviation coordinates of 6 alignment marks in the mask pattern. In the embodiment of the disclosure, each mask pattern may include but not limited to 6 alignment marks, and may further include 64 alignment marks and the like. The number of alignment marks in the mask pattern is not specifically limited in the embodiment of the disclosure.

TABLE 1

| | Own | | Relative | |
|---|---|---|---|---|
| | deviation | | deviation | |
| Serial | coordinate | | coordinate | |
| number | x | y | Δx | Δy |
| 1 | −0.85 | −0.6 | 1.23 | 0.33 |
| 2 | 0.83 | 0.2 | 0.81 | −0.2 |
| 3 | −1.61 | 0.13 | −0.38 | −0.46 |
| 4 | 0.64 | 1.19 | 0.22 | 0.41 |
| 5 | 0.68 | −0.67 | −0.6 | −1.09 |
| 6 | −0.5 | 0.42 | −0.47 | 0.38 |

Therefore, after the relative detection parameters of the mask patterns are acquired from the own detection parameters and the reference detection parameters of the mask patterns, relative deviation vectors are plotted in the layouts of the mask patterns according to each relative deviation coordinate in the relative detection parameters. When the relative deviation vectors are plotted, lines of different colors may be used for plotting, to represent the relative deviation vectors of different vector lengths. Likewise, upon the completion of the plotting of the relative deviation vector, a corresponding vector matrix may be plotted according to the relative deviation vector, such that the influence of the relative deviation on the device structure can be determined intuitively to facilitate subsequent analysis and adjustment.

In some embodiments, when the multiple mask patterns are respectively mask patterns of same film layers of different integrated chips and are manufactured with a same mask plate, a corresponding deviation vector may be directly acquired according to the detection parameter of each mask pattern. The method for acquiring the direction and the vector length of the deviation vector of the deviation coordinate of each alignment mark in the mask pattern according to the detection parameter may be as follows: plotting, according to a detection parameter of each mask pattern, a deviation vector of each alignment mark in each mask pattern, and acquiring the direction and the vector length of the deviation vector. Therefore, in the layouts of the mask patterns, lines of different colors may be used to respectively plot a deviation vector of each mask pattern of different directions and/or vector lengths, such that the direction and the vector length of each deviation vector can be acquired intuitively to facilitate subsequent analysis and adjustment.

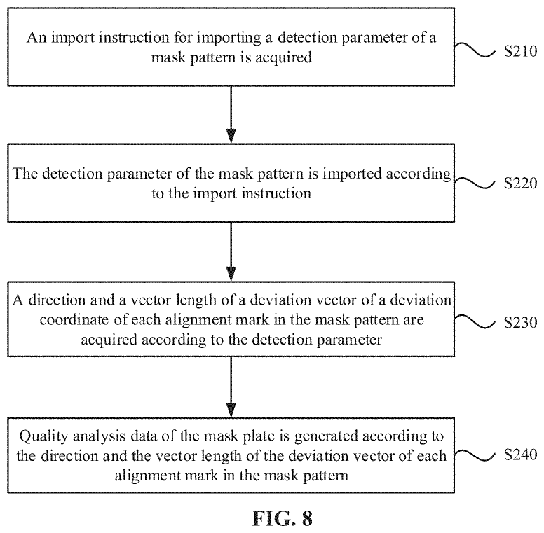

In some embodiments, the mode for acquiring the at least one mask pattern may, for example, be a mode of directly importing the detection data of the mask pattern. FIG. 8 illustrates a flowchart of another method for analyzing a mask plate provided by an embodiment of the disclosure. As shown in FIG. 8, the method includes the following steps:

At S210, an import instruction for importing a detection parameter of the mask pattern is acquired.

At S220, the detection parameter of the mask pattern is imported according to the import instruction.

In some embodiments, upon the complete manufacture of the mask plate, there is a need to detect the mask plate. A corresponding mask pattern may be manufactured with the mask plate, and a measurement coordinate of each alignment mark in the mask pattern is measured, and the measurement coordinate of the alignment mark of the mask pattern is compared with a preset coordinate of an alignment mark in a layout of the mask pattern, to generate detection data of the corresponding mask pattern. The detection data of the mask pattern may be presented in the form of a detection data table. When the performance of the mask plate is analyzed, the detection data table of the mask pattern manufactured with the mask plate may be directly imported. Therefore, the deviation coordinate of each alignment mark is unnecessary to be input manually, to simplify the operation, and avoid the error during manual inputting. The method for analyzing the mask plate provided by the embodiment of the disclosure has simple operation, and can improve the analysis efficiency and accuracy of the mask plate.

At S230, a direction and a vector length of a deviation vector of a deviation coordinate of each alignment mark in the mask pattern are acquired according to the detection parameter.

At S240, quality analysis data of the mask plate are generated according to the direction and the vector length of the deviation vector of each alignment mark in the mask pattern.

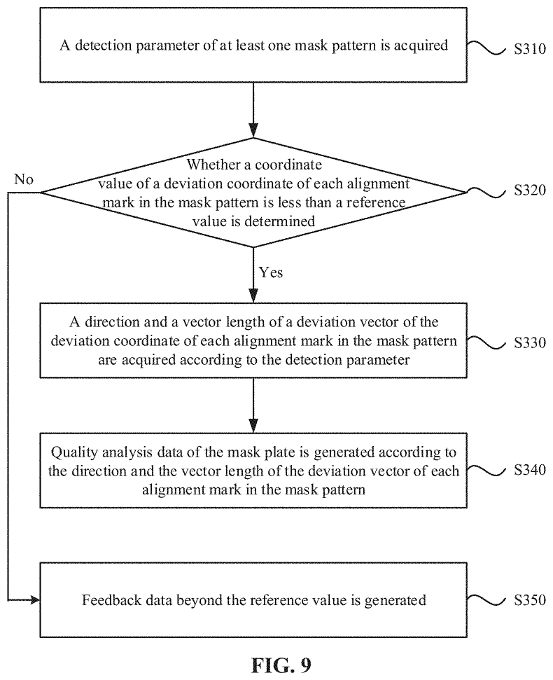

In some embodiments, before the direction and the vector length of the deviation vector of the deviation coordinate of each alignment mark in the mask pattern are acquired, whether a coordinate value of the deviation coordinate of each alignment mark is greater than a reference value may be determined first. FIG. 9 illustrates a flowchart of another method for analyzing a mask plate provided by an embodiment of the disclosure. As shown in FIG. 9, the method includes the following steps:

At S310, a detection parameter of at least one mask pattern is acquired.

At S320, whether a coordinate value of a deviation coordinate of each alignment mark in the mask pattern is less than a reference value is determined; if yes, S330 is executed; and if no, S350 is executed.

At S330, a direction and a vector length of a deviation vector of the deviation coordinate of each alignment mark in the mask pattern are acquired according to the detection parameter.

At S340, quality analysis data of the mask plate are generated according to the direction and the vector length of the deviation vector of each alignment mark in the mask pattern.

At S350, feedback data beyond the reference value are generated.

In some embodiments, before the deviation vector of the deviation coordinate of each alignment mark in the mask pattern is acquired, whether the coordinate value of the deviation coordinate of each alignment mark in the mask pattern is less than the reference value is determined. When the deviation coordinate is greater than the reference value, it may be determined that the mask pattern manufactured with the mask plate cannot meet requirements of an actual device, feedback data may be directly generated, and the subsequent step is not executed; and when the deviation coordinate is less than the reference value, the subsequent step that the corresponding deviation vector is acquired and the quality analysis data of the mask plate is generated according to the deviation vector is executed. Therefore, the feedback can be provided directly when the mask plate does not meet the requirements of the device, thereby improving the detection efficiency. The deviation coordinate may be a positive deviation coordinate or a negative deviation coordinate. For example, x and y in the deviation coordinate (x, y) may be numbers greater than or equal to 0; or x and y in the deviation coordinate (x, y) may be numbers less than or equal to 0; either x or y in the deviation coordinate (x, y) is a number greater than or equal to 0, and the other is a number less than or equal to 0; and the coordinate value of the deviation coordinate may be an absolute value of x and y.

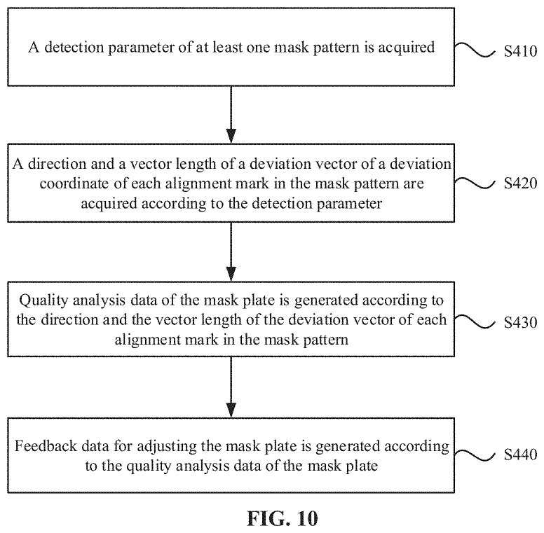

Optionally, after the quality analysis data of the mask plate are generated, feedback data for adjusting the mask plate can further be generated according to the quality analysis data of the mask plate. FIG. 10 illustrates a flowchart of another method for analyzing a mask plate provided by an embodiment of the disclosure. As shown in FIG. 10, the method includes the following steps:

At S410, a detection parameter of at least one mask pattern is acquired.

At S420, a direction and a vector length of a deviation vector of a deviation coordinate of each alignment mark in the mask pattern are acquired according to the detection parameter.

At S430, quality analysis data of the mask plate are generated according to the direction and the vector length of the deviation vector of each alignment mark in the mask pattern.

At S440, feedback data for adjusting the mask plate are generated according to the quality analysis data of the mask plate.

Exemplarily, when the quality analysis data includes a vector length of a deviation vector having a maximum vector length in the mask pattern manufactured with the mask plate, whether the vector length of the deviation vector having the maximum vector length is greater than a reference value may be determined. When the vector length of the deviation vector having the maximum vector length is greater than the reference value, the mask plate for manufacturing the mask pattern may be determined as an unqualified mask plate, and a position of a deviation coordinate and/or an alignment coordinate corresponding to each deviation vector having the vector length of the deviation vector greater than the reference value in the mask pattern manufactured with the mask plate is generated into the feedback data to be fed back to a device manufacturer or a manufacturer of the mask plate, thereby adjusting each data in the mask plate timely in subsequent manufacture of the new mask plate.

Exemplarily, when the quality analysis data includes the vector length of the deviation vector having the maximum vector length in each mask pattern of different film layers in a same integrated chip manufactured with different mask plates, and contrast statistical data of the vector length of the deviation vector having the maximum vector length in the mask pattern of the different film layers in the same integrated chip manufactured with different mask plates, if the vector length of the deviation vector having the maximum vector length in each mask pattern is less than the reference value, a detection parameter of a mask pattern of one film layer may be used as a reference detection parameter, and a detection parameter of a mask pattern of each of other film layers may generate a compensation value for the detection parameter of the mask pattern of each of the other film layers with the reference detection parameter as a reference, such that the sum for the compensated detection parameter of each of the other mask patterns and the reference detection parameter is 0. For example, when the detection parameter of the mask pattern of the first film layer is used as the reference parameter. If the value of the deviation coordinate of the alignment mark in the mask pattern of the first film layer in the X direction is −0.2, the compensation value of the deviation coordinate of the alignment mark at the corresponding portion in the mask pattern of the second film layer in the X direction is set as +0.2, such that in the X direction, the deviation of the deviation coordinate of the alignment mark in the mask pattern of the second film layer relative to the deviation coordinate of the alignment mark of the mask pattern of the first film layer is 0; and the compensated value is fed back to the manufacturer of the device for manufacturing the mask plate or of the mask plate, to compensate the mask plate corresponding to each film layer according to the compensated value.

The embodiments of the disclosure further provide an apparatus for analyzing a parameter of a mask plate. The apparatus may be applied to a situation for analyzing performance and quality of the mask plate. The apparatus for analyzing the parameter of the mask plate provided by the embodiments of the disclosure may be implemented by software and/or hardware. The apparatus for analyzing the parameter of the mask plate may be configured to execute the method for analyzing the parameter of the mask plate provided by the embodiments of the disclosure. The apparatus for analyzing the parameter of the mask plate has the beneficial effects of the method for analyzing the parameter of the mask plate. The beneficial effects of the apparatus for analyzing the parameter of the mask plate provided by the embodiments of the disclosure may be described with reference to the method for analyzing the parameter of the mask plate, and will not be repeated herein.

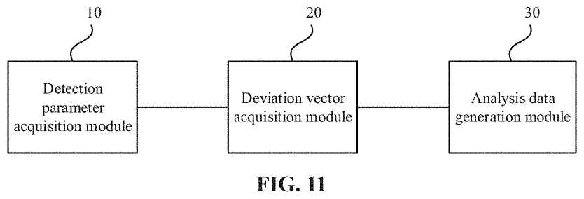

Exemplarily, FIG. 11 illustrates a structural schematic diagram of an apparatus for analyzing a mask plate provided by an embodiment of the disclosure. As shown in FIG. 11, the apparatus for analyzing the mask plate includes: a detection parameter acquisition module 10, a deviation vector acquisition module 20 and an analysis data generation module 30. The detection parameter acquisition module 10 is configured to acquire a detection parameter of at least one mask pattern, wherein the detection parameter includes a deviation coordinate between a measurement coordinate of each alignment mark in a mask pattern manufactured with a mask plate and a preset coordinate of each alignment mark in a layout of the mask pattern; the deviation vector acquisition module 20 is configured to acquire, according to the detection parameter, a direction and a vector length of a deviation vector of the deviation coordinate of each alignment mark in the mask pattern; and the analysis data generation module 30 is configured to generate quality analysis data of the mask plate according to the direction and the vector length of the deviation vector of each alignment mark in the mask pattern.

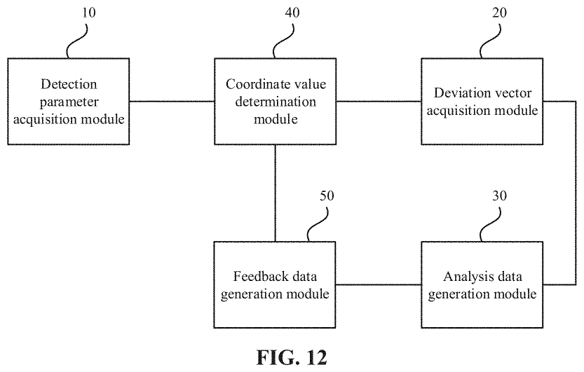

In some embodiments, FIG. 12 illustrates a structural schematic diagram of another apparatus for analyzing a mask plate provided by an embodiment of the disclosure. As shown in FIG. 12, the apparatus for analyzing the mask plate may further include: a coordinate determination module 40 and a feedback data generation module 50. The coordinate determination module 40 is configured to determine, before acquiring the direction and the vector length of the deviation vector of the deviation coordinate of each alignment mark in the mask pattern according to the detection parameter, that whether a coordinate value of the deviation coordinate of each alignment mark in the mask pattern is less than a reference value, and control, when the coordinate value of the deviation coordinate of each alignment mark in the mask pattern is less than the reference value, the deviation vector acquisition module to execute the step of acquiring the direction and the vector length of the deviation vector of the deviation coordinate of each alignment mark in the mask pattern; and the feedback data generation module 50 is configured to generate, when the coordinate value of the deviation coordinate of each alignment mark in the mask pattern is greater than or equal to the reference value, feedback data beyond the reference value.

In some embodiments, referring to FIG. 12 again, the feedback data generation module 50 of the apparatus for analyzing the mask plate is further configured to generate, according to the quality analysis data of the mask plate, feedback data for adjusting the mask plate.

In some embodiments, referring to FIG. 12 again, the detection parameter of the at least one mask pattern acquired by the detection parameter acquisition module 10 may be detection parameters of multiple mask patterns. By this time, the analysis data generation module 30 is specifically configured to generate, according to a vector length average value of the deviation vector of each alignment mark in each mask pattern, a relation diagram between the vector length average value of each mask pattern and a reference value; or, generate, according to a maximum vector length of the deviation vector of each alignment mark in each mask pattern, a relation diagram between the maximum vector length of each mask pattern and a reference value; or, generate, according to a minimum vector length of the deviation vector of each alignment mark in each mask pattern, a relation diagram between the minimum vector length of each mask pattern and a reference value; or, generate, according to a deviation coordinate of the deviation vector having the maximum vector length from the deviation vector of each alignment mark in each mask pattern, a relation diagram between the deviation coordinate of the deviation vector having the maximum vector length in each mask pattern and a reference coordinate; or, generate, according to a deviation coordinate of the deviation vector having the minimum vector length from the deviation vector of each alignment mark in each mask pattern, a relation diagram between the deviation coordinate of the deviation vector having the minimum vector length in each mask pattern and a reference coordinate.

In some embodiments, referring to FIG. 12 again, the multiple mask patterns acquired by the detection parameter acquisition module 10 may respectively be mask patterns of different film layers in a same integrated chip and are manufactured with different mask plates; and a detection parameter of one mask pattern among the detection parameters of the multiple mask patterns is used as a reference detection parameter, and a detection parameter of each of other mask patterns is used as an own detection parameters. By this time, the deviation vector acquisition module 20 is specifically configured to: plot, according to the reference detection parameter and an own detection parameter of each mask pattern, an own deviation vector of each alignment mark in each mask pattern, and acquire a direction and a vector length of the own deviation vector; acquire a relative detection parameter of each mask pattern according to a difference value between the own detection parameter of each mask pattern and the reference detection parameter; and plot, according to the relative detection parameter, a relative deviation vector of each alignment mark in each mask pattern, and acquire a direction and a vector length of the relative deviation vector.

In some embodiments, referring to FIG. 12 again, the multiple mask patterns acquired by the detection parameter acquisition module 10 may respectively be mask patterns of same film layers of different integrated chips and are manufactured with a same mask plate. The deviation vector acquisition module 20 is specifically configured to: plot, according to the detection parameter of each mask pattern, a deviation vector of each alignment mark in each mask pattern, and acquire a direction and a vector length of the deviation vector.

In some embodiments, referring to FIG. 12 again, the detection parameter acquisition module 10 of the apparatus for analyzing the parameter of the mask plate is specifically configured to: acquire an import instruction for importing the detection parameter of the mask pattern, and import the detection parameter of the mask pattern according to the import instruction.

The apparatus for analyzing the parameter of the mask plate provided by the above embodiment may execute the method for analyzing the parameter of the mask plate provided by any embodiment of the disclosure, and has corresponding functional modules for executing the method for analyzing the parameter of the mask plate and beneficial effects. Technical details not described in the above embodiment may refer to the method for analyzing the parameter of the mask plate provided by any embodiment of the disclosure.

It is to be noted that the above are merely embodiments of the disclosure and the utilized technical principles. Those skilled in the art will understand that the disclosure is not limited to the special embodiments described herein. For those skilled in the art, various obvious changes, readjustments, combinations and replacements can be made without departing from the protection scope of the disclosure. Therefore, although the disclosure is described in detail through the above embodiments, the disclosure is not merely limited to the above embodiments, and may further include more other equivalent embodiments without departing the concept of the disclosure. The scope of the disclosure depends on the scope of the appended claims.

1. A method for analyzing a parameter of a mask plate, comprising:
acquiring a detection parameter of at least one mask pattern, wherein the detection parameter comprises a deviation coordinate between a measurement coordinate of each alignment mark in a mask pattern manufactured with the mask plate and a preset coordinate of each alignment mark in a layout of the mask pattern;
acquiring a direction and a vector length of a deviation vector of the deviation coordinate of each alignment mark in the mask pattern according to the detection parameter; and
generating quality analysis data of the mask plate according to the direction and the vector length of the deviation vector of each alignment mark in the mask pattern.

2. The method of claim 1, wherein acquiring the detection parameter of the at least one mask pattern comprises:
acquiring detection parameters of multiple mask patterns; and
generating the quality analysis data of the mask plate according to the direction and the vector length of the deviation vector of each alignment mark in the mask pattern comprises:
acquiring a vector length average value of a deviation vector of each alignment mark in each mask pattern according to the vector length of the deviation vector of each alignment mark in the mask pattern; and
generating, according to the vector length average value of the deviation vector of each alignment mark in each mask pattern and a reference value, a relation diagram between the vector length average value of each mask pattern and the reference value; or,
acquiring a maximum vector length of the deviation vector of each alignment mark in each mask pattern according to the vector length of the deviation vector of each alignment mark in the mask pattern; and
generating, according to the maximum vector length of the deviation vector of each alignment mark in each mask pattern and a reference value, a relation diagram between the maximum vector length of each mask pattern and the reference value; or,
acquiring a minimum vector length of the deviation vector of each alignment mark in each mask pattern according to the vector length of the deviation vector of each alignment mark in the mask pattern; and
generating, according to the minimum vector length of the deviation vector of each alignment mark in each mask pattern and a reference value, a relation diagram between the minimum vector length of each mask pattern and the reference value; or,
acquiring a deviation vector having a maximum vector length from the deviation vector of each alignment mark in each mask pattern, according to the vector length of the deviation vector of each alignment mark in the mask pattern;
acquiring a deviation coordinate of the deviation vector having the maximum vector length from the deviation vector of each alignment mark in each mask pattern, according to the detection parameters of the multiple mask patterns; and
generating, according to the deviation coordinate of the deviation vector having the maximum vector length from the deviation vector of each alignment mark in each mask pattern, a relation diagram between the deviation coordinate of the deviation vector having the maximum vector length in each mask pattern and a reference coordinate; or,
acquiring a deviation vector having a minimum vector length from the deviation vector of each alignment mark in each mask pattern, according to the vector length of the deviation vector of each alignment mark in the mask pattern;
acquiring a deviation coordinate of the deviation vector having the minimum vector length from the deviation vector of each alignment mark in each mask pattern, according to the detection parameters of the multiple mask patterns; and
generating, according to the deviation coordinate of the deviation vector having the minimum vector length from the deviation vector of each alignment mark in each mask pattern, a relation diagram between the deviation coordinate of the deviation vector having the minimum vector length in each mask pattern and a reference coordinate.

3. The method of claim 2, wherein the multiple mask patterns are respectively mask patterns of different film layers in a same integrated chip and are manufactured with different mask plates; and a detection parameter of one mask pattern among the multiple mask patterns is used as a reference detection parameter, and a detection parameter of each of other mask patterns than the one mask pattern among the multiple mask patterns is used as an own detection parameter; and
acquiring the direction and the vector length of the deviation vector of the deviation coordinate of each alignment mark in the mask pattern according to the detection parameter comprises:
plotting, according to the reference detection parameter and the own detection parameter, an own deviation vector of each alignment mark in each mask pattern, and acquiring a direction and a vector length of the own deviation vector;
acquiring a relative detection parameter of each mask pattern according to a difference value between each own detection parameter and the reference detection parameter; and
plotting, according to the relative detection parameter, a relative deviation vector of each alignment mark in each mask pattern, and acquiring a direction and a vector length of the relative deviation vector.

4. The method of claim 2, wherein the multiple mask patterns are respectively mask patterns of same film layers of different integrated chips and are manufactured with a same mask plate; and
acquiring the direction and the vector length of the deviation vector of the deviation coordinate of each alignment mark in the mask pattern according to the detection parameter comprises:
plotting, according to the detection parameter of each mask pattern, a deviation vector of each alignment mark in each mask pattern, and acquiring the direction and the vector length of the deviation vector.

5. The method of claim 1, wherein acquiring the detection parameter of the at least one mask pattern comprises:
acquiring an import instruction for importing the detection parameter of the mask pattern; and
importing the detection parameter of the mask pattern according to the import instruction.

6. The method of claim 1, further comprising:
executing, in response to determining that a coordinate value of the deviation coordinate of each alignment mark in the mask pattern is less than a reference value, the step of acquiring the deviation vector of the deviation coordinate of each alignment mark in the mask pattern according to the detection parameter; and
generating, in response to determining that the coordinate value of the deviation coordinate of each alignment mark in the mask pattern is greater than or equal to the reference value, feedback data beyond the reference value.

7. The method of claim 1, further comprising:
generating, according to the quality analysis data of the mask plate, feedback data for adjusting the mask plate.

8. An apparatus for analyzing a parameter of a mask plate, comprising:
a detection parameter acquisition module, configured to acquire a detection parameter of at least one mask pattern, wherein the detection parameter comprises a deviation coordinate between a measurement coordinate of each alignment mark in a mask pattern manufactured with a mask plate and a preset coordinate of each alignment mark in a layout of the mask pattern;
a deviation vector acquisition module, configured to acquire, according to the detection parameter, a direction and a vector length of a deviation vector of the deviation coordinate of each alignment mark in the mask pattern; and
an analysis data generation module, configured to generate quality analysis data of the mask plate according to the direction and the vector length of the deviation vector of each alignment mark in the mask pattern.

9. The apparatus of claim 8, further comprising:
a coordinate determination module, configured to control, in response to determining that a coordinate value of the deviation coordinate of each alignment mark in the mask pattern is less than a reference value, the deviation vector acquisition module to execute the step of acquiring the direction and the vector length of the deviation vector of the deviation coordinate of each alignment mark in the mask pattern; and
a feedback data generation module, configured to generate, in response to determining that the coordinate value of the deviation coordinate of each alignment mark in the mask pattern is greater than or equal to the reference value, feedback data beyond the reference value.

10. The apparatus of claim 8, further comprising:
a feedback data generation module, configured to generate, according to the quality analysis data of the mask plate, feedback data for adjusting the mask plate.
